(19) United States
(12) Patent Application Publication
(10) Pub. No.: US 2004/0053510 A1
(43) Pub. Date: Mar. 18, 2004

(54) System for and method of unlimited voltage multi ported sram cells

(76) Inventors: Casey J. Little, Fort Collins, CO (US); Reid J. Riedlinger, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 10/244,212

(22) Filed: Sep. 16, 2002

(51) Int. Cl. H01L 21/31

(52) U.S. Cl. 438/776

(57) ABSTRACT

A system and method of a RAM cell write circuit of a multi-ported RAM cell, including a first Field Effect Transistor (FET) having a gate connected to a first port not write bitline, and a second FET having a gate connected to a first port write wordline and, clear logic controlled by the first bitline and first wordline, the clear logic setting the memory element to a first value when said first bitline and said first wordline are active.

### RELATED APPLICATIONS

The present application is related to commonly assigned U.S. Pat. No. 6,208,565, entitled “MULTI-PORTED REGISTER STRUCTURE UTILIZING A PULSE WRITE MECHANISM” and U.S. Pat. No. 6,226,217, entitled “REGISTER STRUCTURE WITH A DUAL-ENDED WRITE MECHANISM”, the disclosure of which are hereby incorporated by reference in their entireties.

### FIELD OF THE INVENTION

The present invention relates generally to integrated circuits, and more particularly, to techniques and circuits for storing data in a static random access memory.

### BACKGROUND

Computer systems may employ a multi-level hierarchy of memory, with relatively fast, expensive memory at the highest level of the hierarchy and relatively slower, lower cost memory at the lowest level of the hierarchy. The fast, expensive memory at the highest level is typically limited in its capacity while the slower, lower cost memory at the lowest level is higher-capacity memory. The highest level of the memory hierarchy may be implemented using register structures, which are typically limited in capacity but provide very fast access. Such register structures may be referred to as “register files,” and various such register structures, such as an integer register structure and floating point register structure, may be implemented in a system. A register structure enables high speed memory access and is typically capable of satisfying a memory access request (e.g., a read or write request) in one clock cycle (i.e., one processor clock cycle). Various lower levels of memory may also be implemented within the multi-level hierarchy of memory including a small fast memory called a cache. Cache may be physically integrated within a processor or mounted physically close to the processor for speed. The main memory (e.g., the disk drive) of a computer system is also part of the memory hierarchy.

Static Random Access Memory (SRAM) is typically implemented as register structures for storing data in a computer system. Generally, SRAM memory is very reliable and very fast. Unlike Dynamic Random Access Memory (DRAM), SRAM does not need to have its electrical charges constantly refreshed. As a result, SRAM memory is typically faster and more reliable than DRAM memory. Unfortunately, SRAM memory is generally much more expensive to produce than DRAM memory. Due to its high cost, SRAM is typically implemented only for the most speed-critical parts of a computer, such as memory caches. However, SRAM memory may be implemented for other memory components of a computer system, as well. Moreover, other types of memory (e.g., other types of RAM) may be implemented within a computer system for a register structure.

To enable greater efficiency in processing instructions, multiple ports or access points are commonly implemented within a computer system. For instance, multiple ports may be implemented such that each port is capable of satisfying a memory access request (e.g., a read or write instruction) in parallel with other ports that are satisfying other memory access requests. In other words, multiple ports may share a SRAM location. Accordingly, various memory caches have been developed to enable access to the SRAM location by multiple ports. That is, multiported RAM cell structures are commonly implemented to enable multiple ports to access the memory caches to satisfy a memory access request. Typically a single port is used to access a memory cache at a specific time.

### SUMMARY

One embodiment of the present invention comprises a RAM cell write circuit of a multi-ported RAM cell, comprising a first Field Effect Transistor (FET) having a gate connected to a first port not write bitline, a second FET having a gate connected to a first port write wordline, and clear logic controlled by the first bitline and first wordline, the clear logic setting the memory element to a first value when said first bitline and said first wordline are active.

### BRIEF DESCRIPTION

FIG. 1 illustrates a typical single-ported dual-ended SRAM cell;

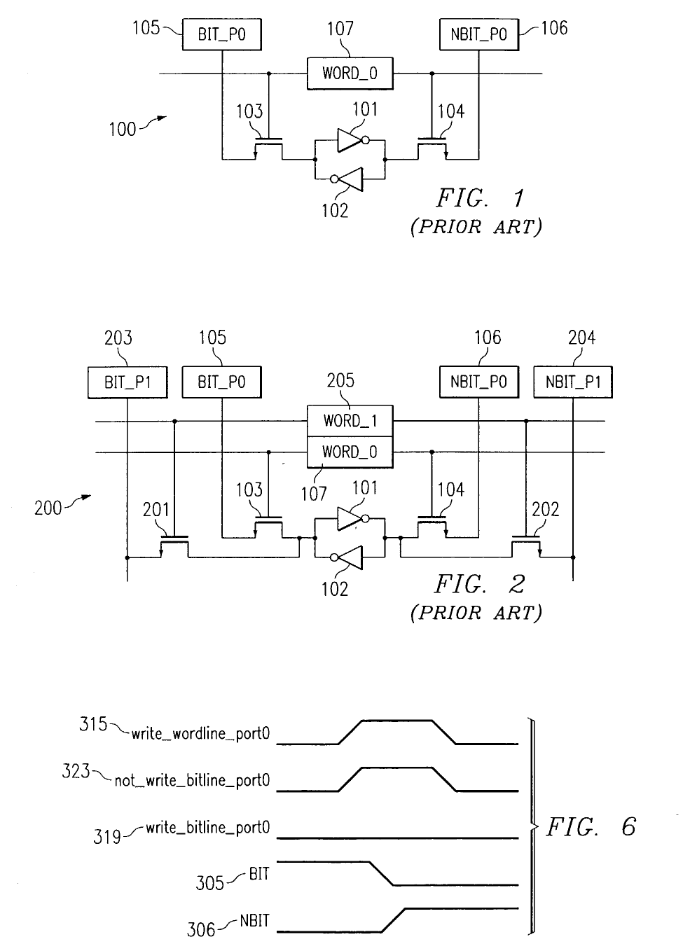

FIG. 2 illustrates a typical two ported dual-ended SRAM cell;

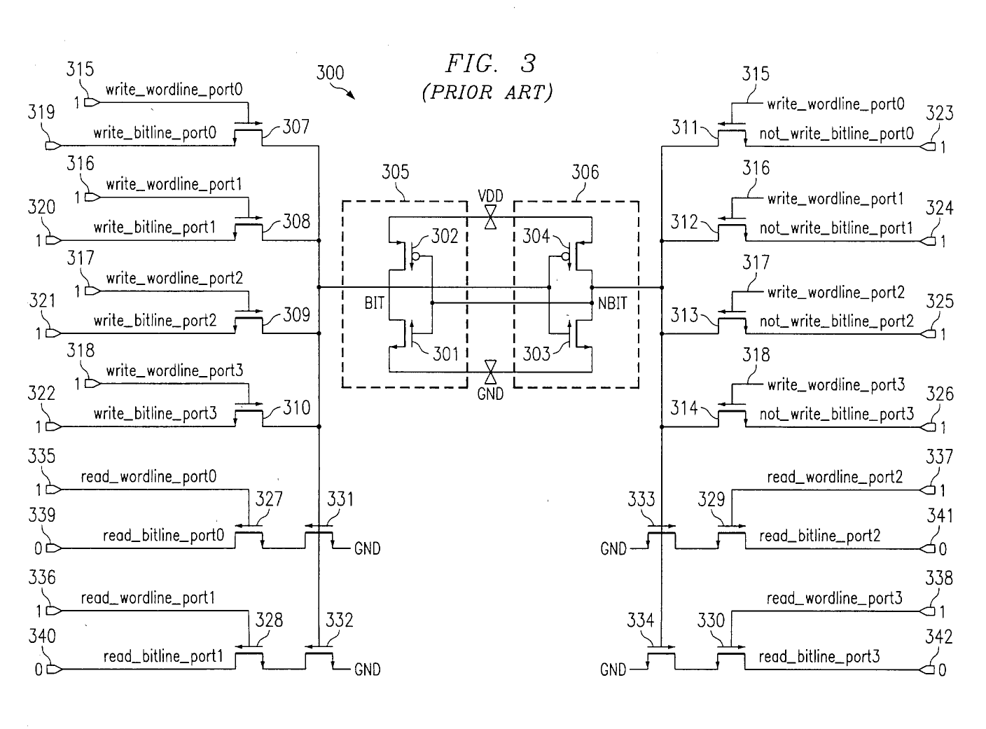

FIG. 3 illustrates a four-ported dual-ended SRAM cell;

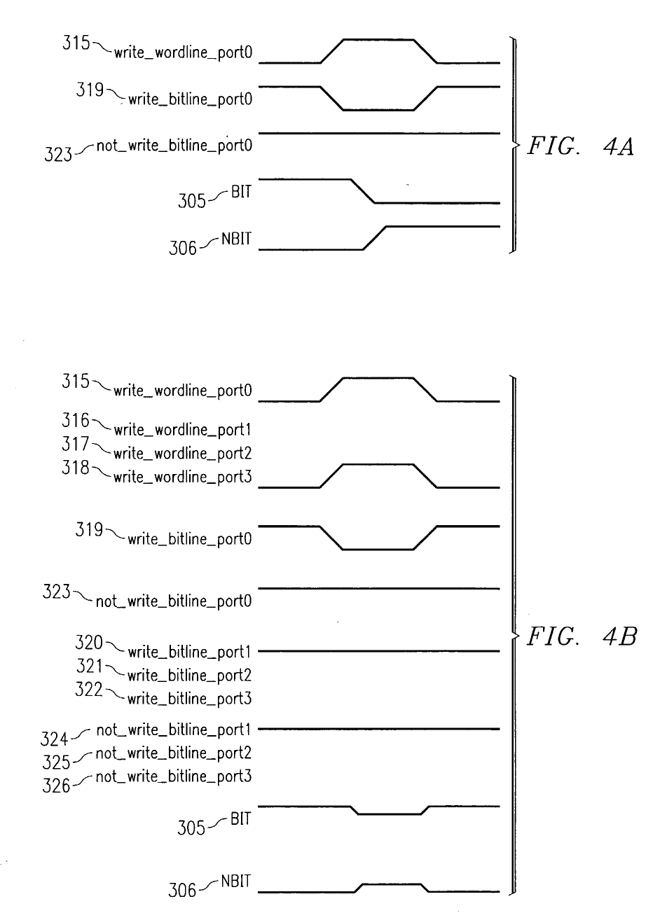

FIG. 4A illustrates the normal operation of a RAM cell;

FIG. 4B illustrates a write failure typical for four-ported RAM cells;

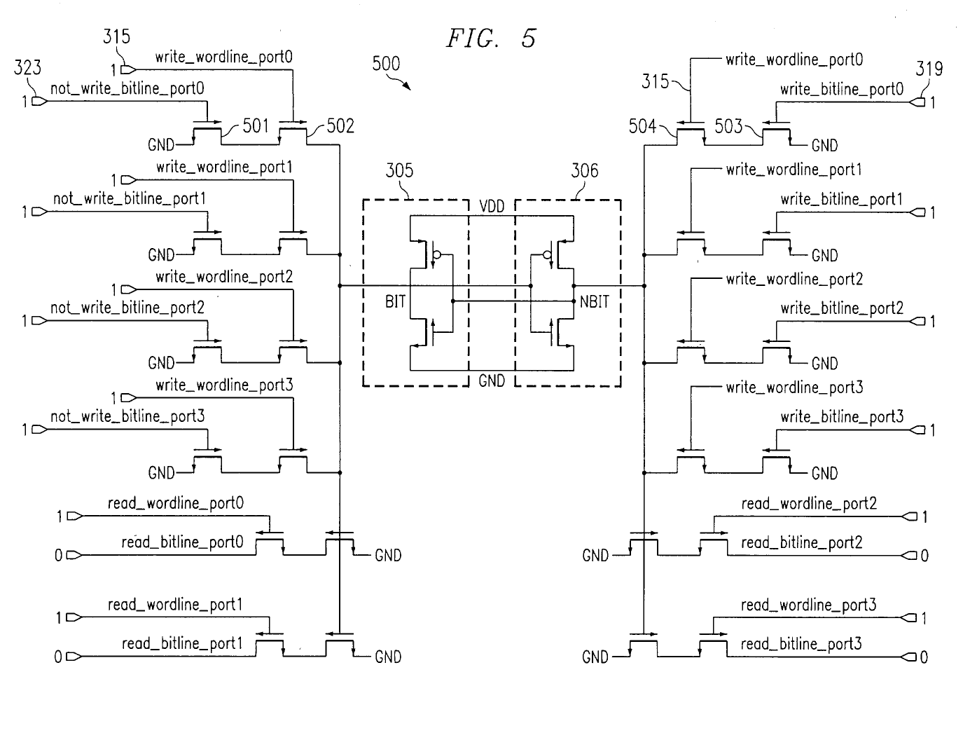

FIG. 5 illustrates an embodiment of a RAM cell in one embodiment of the present invention; and

FIG. 6 illustrates the operation of the SRAM cell in one embodiment of the present invention.

### DETAILED DESCRIPTION

FIG. 1 illustrates a typical single-ported dual ended Static Random Access Memory (SRAM) cell 100. Memory caches of the prior art are typically implemented with dual-ended writes through an N-channel Field Effect Transistor (NFET) into a latch. The single-ported SRAM structure of FIG. 1 comprises a typical SRAM cell 100 comprising cross-coupled inverters 101 and 102 for storing data (i.e., for storing one bit of data). NFETs 103 and 104 enable writes from a first port (i.e., port 0). In FIG. 1, port 0 corresponds to lines BIT_P0 105 and NBIT_P0 106. A write is accomplished to the SRAM cell by passing a voltage level across NFETs 103 and 104 into the cross-coupled inverters 101 and 102. SRAM cell 100 of FIG. 1 is a memory cell capable of storing one bit of data (i.e., a logic 1 or a logic 0). Thus, many of such SRAM cells 100 must be implemented within a system to provide the desired amount of SRAM memory. When many SRAM cells are used in a memory the combination of the bit lines and the word lines ensures a read or write occurs on the correct SRAM cell. Typically both the word line and the bit line are connected to a number of SRAM cells. The word line is connected to a number of memory cells in a row and the bit line is connected to a number of memory cells in a column. In addition the bit line provides the value that is to be written to the Random Access Memory (RAM) cell.

Port 0 coupled to SRAM cell 100 may write data into the cell to satisfy a memory access request (e.g., a memory write request). As shown, BIT_P0 105, NBIT_P0 106, and WORD_0 lines 107 are implemented to enable a write for port 0 to SRAM cell 100. BIT_P0 105 may be referred to as the data carrier for port 0, and NBIT_P0 106 may be referred to as a complementary data carrier for port 0. Note that the operation of SRAM cell 100 is well known and, therefore, will be described only briefly herein. Typically, the BIT_P0 line 105 is held to a high voltage level (i.e., a logic 1), unless it is actively pulled to a low voltage level (i.e., a logic 0). For instance, when writing data from port 0 to SRAM cell 100, BIT_P0 line 105 is actively driven low and NBIT_P0 line 106 is held to a high voltage level. Alternatively, if an outside source desired to write a 1 to SRAM cell 100, BIT_P0 line 105 remains high and NBIT_P0 line 106 is pulled low. WORD_0 line 107 is then fired (e.g., caused to go to a high voltage level), at which time the value of BIT_P0 line 105 is written into SRAM cell 100. When WORD_0 line 107 is fired, NFETs 103 and 104 are biased on. More specifically, the voltage level of BIT_P0 is transferred across NFET 103 and the voltage level of NBIT_P0 is transferred across NFET 104 to accomplish a write of the value of BIT_P0 to cross-coupled inverters 101 and 102. When WORD_0 line 107 is “off” or at a zero value the value stored in the RAM cell remains unchanged.

FIG. 2 illustrates a typical two-ported dual-ended SRAM cell 200 of the prior art. As with FIG. 1, this memory cache is typically implemented with dual-ended writes through an NFET into a latch. The two-ported SRAM structure of FIG. 2 comprises a typical SRAM cell comprising cross-coupled inverters 101 and 102 for storing data (i.e., for storing one bit of data). Additionally, NFETs 103 and 104 are provided that enable writes from a first port (i.e., port 0 having lines BIT_P0 105 and NBIT_P0 106). A write is accomplished to the SRAM cell by passing a voltage level across NFETs 103 and 104 into the cross-coupled inverters 101 and 102. Also, a second port (i.e., port 1 having lines BIT_P1 203 and NBIT_P1 204) is coupled to SRAM cell 200 by adding NFETs 201 and 202, which enable writes from the second port (port 1) to the SRAM cell 200. Note that the two-ported SRAM structure 200 of FIG. 2 is commonly implemented in integrated circuits. The SRAM cell 200 is a memory cell capable of storing one bit of data (i.e., a logic 1 or a logic 0). Thus, many of such SRAM cells 200 must be implemented within a system to provide the desired amount of SRAM memory.

Either of the two ports (i.e., port 0 and port 1) coupled to the SRAM cell 200 may write data into the cell to satisfy a memory access request (e.g., a memory write request). As shown, BIT_P0 105, NBIT_P0 106, and WORD_0 lines 107 are implemented to enable a write for port 0 to SRAM cell 200, and BIT_P1 203, NBIT_P1 204 and WORD_1 205 lines are implemented to enable a write for port 1 to SRAM cell 200. BIT_P0 105 and BIT_P1 203 lines may be referred to herein as data carriers for port 0 and port 1, respectively, and NBIT_P0 106 and NBIT_P1 204 lines may be referred to herein as complementary data carriers for port 0 and port 1, respectively. As previously described with respect to the single-port SRAM cell 100, BIT_P0 105 and BIT_P1 203 lines are held to a high voltage level (i.e., a logic 1), unless one of them is actively pulled to a low voltage level (i.e., a logic 0). For instance, when writing data from port 0 to SRAM cell 200, BIT_P0 line 105 is actively driven low by an outside source (e.g., an instruction being executed by the processor) and NBIT_P0 line 106 is held to a high voltage level (the opposite of BIT_P0). Otherwise if an outside source desired to write a 1 to SRAM cell 200, BIT_P0 line 105 remains high and NBIT_P0 line 106 is pulled low. Thereafter, WORD_0 line 107 is fired (e.g., caused to go to a high voltage level), at which time the value of BIT_P0 line 105 is written into SRAM cell 200. More specifically, the voltage level of BIT_P0 is transferred across NFET 103 and the voltage level of NBIT_P0 is transferred across NFET 104 to accomplish a write of the value of BIT_P0 to cross-coupled inverters 101 and 102.

A similar operation is performed when writing data from port 1 to SRAM cell 200. For instance when writing data from port 1 to SRAM cell 200, BIT_P1 line 203 is actively driven low by an outside source (e.g., an instruction being executed by the processor) and NBIT_P1 line 204 is held to a high voltage level (the opposite of BIT_P1 line 203 ). Otherwise, if an outside source desires to write a 1 to SRAM cell 200, BIT_P1 line 203 remains high and NBIT_P1 line 204 is pulled low. Thereafter WORD_1 line 205 is fired, at which time the value of BIT_P1 line 203 is written into SRAM cell 200. More specifically, the voltage level of BIT_P1 is transferred across NFET 201 and the voltage level of NBIT_P1 is transferred across NFET 202 to accomplish a write of the value of BIT_P1 to cross-coupled inverters 101 and 102. The data value written into SRAM cell 200 (e.g., a logic 0 or logic 1) may be referred to as DATA and the complement of such value may be referred to as NDATA.

The SRAM memory cell illustrated in FIGS. 1 and 2 are referred to as a dual-ended write structure because they utilize both a data carrier (e.g., a BIT line) and a complementary data carrier (e.g., an NBIT line) to write a data value into SRAM cell 100 or 200. For instance, referring to FIG. 2, a BIT_P0 line 105 value and NBIT_P0 line 106 value are both required to write a value to SRAM cell 200 for port 0, and a BIT_P1 line 203 value and NBIT_P1 line 204 value is required to write a value to SRAM cell 200 from port 1.

Typically, multiple SRAM cells are connected to a single data carrier (e.g., BIT line) and a single complementary data carrier (e.g., NBIT line) for a port. Accordingly, a single BIT line may be utilized to carry data to/from multiple SRAM cells for a port. Therefore, even though only a single SRAM cell is shown in FIGS. 1 and 2, it should be understood that many such SRAM cells may be connected to BIT_P0 line 105 and NBIT_P0 line 106 for port 0, as well as to BIT_P1 line 203 and NBIT_P1 line 204 for port 1, to form a group of SRAM cells. Similarly, additional ports may be coupled to the SRAM cell. Thus, even though only two ports (ports 0 and port 1) are shown as being coupled to SRAM cell 200, another SRAM cell may have any number of ports coupled to the SRAM cell. In general, the advantage of having more ports is an increase in the number of instructions that may be processed in parallel, thereby increasing the efficiency of a system.

Multi-ported SRAM structures are problematic in that they require an undesirably large amount of surface area for their implementation. That is, an undesirably large number of components and high-level metal tracks are required to be implemented for each port coupled to the SRAM cell to perform write operations. Thus, multi-ported memory structures are generally used in small, relatively fast, expensive but limited-capacity memory arrays. Single ported memory structures are generally used in large, relatively slower, lower cost but higher-capacity memory arrays.

FIG. 3 illustrates a four-ported dual ended SRAM cell 300. FIG. 3 contains NFET 301 and P-channel Field Effect Transistor (PFET) 302 and NFET 303 and PFET 304. Note that an NFET and a PFET working together may act as an inverter. NFET 301 and PFET 302 together comprise inverter 305 and NFET 303 and PFET 304 together comprise inverter 306. The combination of NFET 301 and PFET 302 may also be referred to as the BIT portion of SRAM Cell 300. The combination of NFET 303 and PFET 304 may be referred to as the NBIT portion of SRAM Cell 300. FIG. 3 also includes four NFETs on the left side of inverter 305: NFET 307, NFET 308, NFET 309 and NFET 310. Similarly, FIG. 3 includes four NFETs on the right side of inverter 306: NFET 311, NFET 312, NFET 313 and NFET 314. As previously described, a voltage applied to a word line is used to bias an NFET on. In FIG. 3, a voltage applied to write_wordline_port0 315 biases both NFET 307 and NFET 311 on, allowing the data on write_bitline_port0 319 to be stored in SRAM cell 300.

Similarly, a voltage applied to write_wordline_port1 316 biases both NFET 308 and NFET 312 on, allowing the data on write_bitline_port1 320 to be stored in SRAM cell 300. A voltage applied to write_wordline_port2 317 biases both NFET 309 and NFET 313 on, allowing the data on write_bitline_port2 321 to be stored in SRAM cell 300. A voltage applied to write_wordline_port3 318 biases both NFET 310 and NFET 314 on, allowing the data on write_bitline_port3 322 to be stored in SRAM cell 300. Each of these actions occurs on the DATA side of SRAM cell 300.

On the NDATA side, a similar action occurs except that each of the values on the corresponding bitline ports contains a value in opposition to the value available on corresponding bitline port on the DATA side. On the NDATA side, when write_wordline_port1 315 fires, biasing both NFET 307 and NFET 311 on, not_write_bitline_port0 323 applies a value complementary to the value on write_bitline_port0 319. Similarly, when write_wordline_port1 316 fires, biasing both NFET 308 and NFET 312 on, not_write_bitline_port1 324 applies a value complementary to the value on write_bitline_port1 320. When write_wordline_port2 317 fires, biasing both NFET 309 and NFET 313 on, not_write_bitline_port2 325 applies a value complementary to the value on write_bitline_port2 321. When write_wordline_port3 318 fires biasing both NFET 310 and NFET 314 on, not_write_bitline_port3 326 applies a value complementary to the value on write_bitline_port3 322. Each of these complementary values applied on the not_write_bitline ports ensure the correct value is stored in SRAM cell 300.

SRAM cell 300 of FIG. 3 also includes eight NFETs (327-334) that are used in read operations. Note that the same NFET may be used for read and write operations, or the read and write operations may be divided between different NFETs. In the configuration shown, each read port requires two NFETs. By the inclusion of separate read NFETs, a read operation and a write operation may occur in different cycle phases. Also note that, as shown in FIG. 3, read_bitline_port2 341 and read_bitline_port3 342 would both read complimentary values that would need to be changed in order to accurately reflect the value currently stored in SRAM cell 300.

In general, in a write operation, a voltage on a wordline port biases a NFET at which time the value on the associated bitline port working with the corresponding not_bitline port, couples the value into the RAM cell. In general, on a read, a voltage on a wordline port biases a NFET at which time the actual inverters drive their value onto the associated bit lines. These values are then read out of the array. The inclusion of separate read and write sections in SRAM cell 300 enables read and write operations to be accomplished during different phases. Generally a read operation takes longer than a write operation.

Stability problems arise in multi-ported RAM cells when the stored value stored in the RAM cell is not maintained. One example of a RAM cell stability problem occurs when a read causes the value stored in the RAM cell to change. Typically, bit lines are pre-charged (have a high voltage or a logical one applied) before a read or a write occurs. Referring again to FIG. 3, write_bitline_port0—write_bitline_port3 (319-322), not_write_bitline_port0—not_write_bitline_port3 (323-326) and read_bitline_port0_read_bitline_port3 (339-342) are each precharged prior to a read or a write operation. These bitlines are typically not held at the high voltage but are allowed to “float” from this high voltage level. When a word line is enabled, the associated NFET is biased on and the voltage applied to the bit line is felt on the RAM cell. The application of this voltage on the RAM cell may cause the value stored in the RAM cell to change. This problem occurs on the “zero” side of the RAM cell when a “pre-charge” high voltage is applied. The possibility of stability problems erroneously changing the value stored in the RAM cell increases as the number of simultaneous read operations increases. Note that read_wordline_port0 read_wordline_port3 (335-338) are used to bias NFETs 327-330 respectively.

FIG. 4A illustrates the normal operation of a RAM cell. To write a zero into RAM cell 300, the value on write_wordline_port0 315 transitions from a zero to a one and the value on write_bitline_port0 319 transitions from a one to a zero. At the same time the value on not write_bitline_port0 323 remains at a high voltage and a logical zero is stored into BIT 305 while a logical one is stored into NBIT 306.

FIG. 4B illustrates a write failure typical to four-ported RAM cells. To write a zero into RAM cell 300, the value on write_wordline_port0 315 transitions from a zero to a one, and the value on write_bitline_port0 319 transitions from a one to a zero. At the same time, the value on not write_bitline_port0 323 remains at a high voltage. As previously described, a one is typically applied to write_bitline_port1 320 through write_bitline_port3 (320-322) and to not_write_bitline_port1 324 through not_write_bitline_port3 (324-326). As previously described, write_bitline_port1 through write_bitline_port3 322 is pre-charged with a 1, as well as not_write_bitline_port1 324 through not_write_bitline_port3 326, and allowed to float during the subsequent write. The value on write_wordline_port1 through write_wordline_port3 (316-318) may also transition from a zero to a one, if a one was placed on each of ports1 through 3 to access other memory cells through the intersection of these wordlines and other bitlines. In these circumstances, because of the high voltages applied to RAM cell 300, the zero may not be stored in BIT 305 and the one may not be stored in NBIT 306. This occurs because the pre-charged bitlines are now applying a “1” to the RAM cell as Port 0 is applying a “0” to the RAM cell, which is referred to as a “drive fight.” This drive fight may prevent storage of the proper value. The drive fight may include three pre-charged ports applying a “1” with a single port applying a “0.”

FIG. 5 illustrates one embodiment of RAM cell 500 of the current invention. As shown, each of the write circuits of RAM cell 500 now includes two NFETs. More specifically, not write_bitline_port0 323 is electrically connected to the gate of NFET 501 and the source of NFET 501 is electrically connected to ground. Write_wordline_port0 315 is electrically connected to the gate of NFET 502 with the source of NFET 502 connected to the drain of NFET 501. The drain of NFET 502 is electrically connected to invertor 305.

As a first example, the operation of the circuit will be explained in the context of storing a zero in BIT 305, which is currently storing a one, and wherein a zero is currently stored in NBIT 306. In this case, a one will be applied to not write_bitline_port0 323, and a zero will be applied to write_bitline_port0 319. A value of one is also applied to write_wordline_port0 315. The one applied to not write_bitline_port0 323 will bias NFET 501 on, and the one applied to write_wordline_port0 315 will bias NFET 502 on. The one applied to write_wordline_port0 315 will also bias NFET 504 on, but the zero applied to write_bitline_port0 319 will ensure NFET 503 is biased off. In this configuration, the desired write of a zero to BIT 305 occurs when the ground connected to the source of the biased NFET 501 is passed through NFET 501 to the drain of NFET 501 that is electrically connected to the source of biased NFET 502 that ensures the ground is present on the drain of NFET 502 that, in turn, is electrically connected to BIT 305. The presence of the ground, or zero, on BIT 305 forces BIT 305 to store the zero. The operation, as described causes a single ended write to occur within BIT 305. In response to the zero being stored in BIT 305, the inverters will cause a one to be stored into NBIT 306.

FIG. 6 illustrates the operation of the SRAM cell 500 of FIG. 5. As discussed in the example, at an initial point BIT 305 stores a one and NBIT 306 stores a zero. In order to store a zero into BIT, a one is applied to write_wordline_port0 315, a one is applied to not-write_bitline_port0 323 and a zero is applied to write_bitline_port0 319. The application of these voltages causes the one stored in BIT 305 to be replaced with a zero, and the value zero stored in NBIT, through the invertors, is replaced with a one.

As a second example, the operation of the circuit will be explained in the context of storing a one in BIT 305, which is currently storing a zero, and wherein a one is currently stored in NBIT 306. In this case, a one will be applied to write_bitline_port0 319, and a zero will be applied to not₁₃ write_bitline_port0 323. A value of one is also applied to write_wordline_port0 315. The one applied to write_bitline_port0 319 will bias NFET 503 on, and the one applied to write_wordline_port0 315 will bias NFET 504 on. The one applied to write_wordline_port0 315 will also bias NFET 502 on, but the zero applied to not_write_bitline_port0 323 will ensure NFET 501 is biased off. In this configuration, the desired write of a zero to NBIT 306 occurs when the ground connected to the source of the biased NFET 503 is passed through NFET 503 to the drain of NFET 503, which is electrically connected to the source of biased NFET 504. This ensures that the ground is present on the drain of NFET 504, which, in turn, is electrically connected to NBIT 306. The presence of the ground, or zero, on NBIT 306 forces NBIT 306 to store the zero. The operation, as described causes a single ended write to occur within NBIT 306. In response to the zero being stored in NBIT 306, the inverters will cause a one to be stored into BIT 305.

Note that the present invention performs a single ended write to occur with the SRAM cell. When a one is stored in BIT 305 and a zero is stored in NBIT 306, the single ended write of a zero into BIT 305 occurs from the left hand side of FIG. 5, and results in one being stored into NBIT 306 through the invertors. Alternatively, when a zero is stored in BIT 305 and a one is stored in NBIT 306, the single ended write of a zero into NBIT 306 occurs from the right hand side of FIG. 5 and results in a one being stored in BIT 305.

What is claimed is:

1. A Random Access Memory (RAM) cell write circuit of a multi-ported RAM cell comprising:
a first Field Effect Transistor (FET), including a gate connected to a first port not write bitline; and,
a second FET, including a gate connected to a first port write wordline.

2. The RAM cell write circuit of claim 1 wherein said first FET and said second FET are selected from the group consisting of NFET and PFET transistors.

3. The RAM cell write circuit of claim 1 wherein a source of said first FET is electrically connected to a low voltage level.

4. The RAM cell write circuit of claim 3 wherein said low voltage level is ground.

5. The RAM cell write circuit of claim 1 wherein a drain of said first FET is electrically connected to a source of said second FET.

6. The RAM cell write circuit of claim 1 wherein a drain of said second FET is electrically connected to a RAM cell.

7. The RAM cell write circuit of claim 6 wherein said drain of said second FET is electrically connected to a BIT portion of said RAM cell.

8. The RAM cell write circuit of claim 1 wherein a source of said first FET is electrically connected to a ground, a drain of said first FET is electrically connected to a source of said second FET and a drain of said second FET is electrically connected to a BIT portion of a RAM cell.

9. The RAM cell write circuit of claim 1 further including:
a RAM cell read circuit.

10. The RAM cell write circuit of claim 1 wherein said first FET and said second FET cooperatively operate as an inverter.

11. The RAM cell write circuit of claim 10 wherein said first and said second FETs are selected from the group consisting of NFETs and PFETs.

12. The RAM cell write circuit of claim 1 wherein said RAM cell write circuit is comprised of at least two NFETs.

13. A multi-ported memory cell comprising:
a first write port including a first Field Effect Transistor (FET) controlled by a first bitline and a second FET controlled by a first wordline, a source of said second FET electrically connected to a drain of said first FET and a drain of said second FET electrically connected to a memory element; and,
a clear logic controlled by first bitline and first wordline, said clear logic setting said memory element to a first value when said first bitline and said first wordline are active.

14. The memory cell of claim 13 wherein:
a source of said first FET is electrically connected to a ground.

15. A method of storing a value within a multi-ported memory cell, said method comprising:
electrically connecting a source of a first Field Effect Transistor (FET) to a low voltage;
biasing said first FET by applying a first control voltage to a gate of said first FET;
biasing a second FET by applying a second control voltage to a gate of said second FET, and;
connecting said low voltage from said source of said first FET, through said biased first and second FETs to a memory cell.

16. The method of claim 15 wherein said step of connecting said low voltage produces a single ended write to said first FET and said second FET.
